(19) United States
(12) Patent Application Publication
(10) Pub. No.: US 2012/0236369 A1
(43) Pub. Date: Sep. 20, 2012

(54) COLOR IMAGING ARCHIVAL SYSTEM

(75) Inventor: Ajay Pasupuleti, Pittsford, NY (US)

(73) Assignee: Nanoark Corporation, Fairport, NY (US)

(21) Appl. No.: 13/430,149

(22) Filed: Mar. 26, 2012

Related U.S. Application Data
(63) Continuation-in-part of application No. 11/956,911, filed on Dec. 14, 2007, now Pat. No. 8,155,427.
(60) Provisional application No. 60/884,768, filed on Jan. 12, 2007.

(51) Int. Cl. H01L 21/31; H04N 1/04; H01L 29/02

(52) U.S. Cl. 358/474; 257/649; 257/632; 438/703; 257/E29.002; 257/E21.24

(57) ABSTRACT

A system for the long-term storage and high-speed retrieval of color images stored on semiconductor substrates. The images are stored on semiconductor substrates by utilizing semiconductor fabrication techniques to produce a plurality of images. A transparent thin-film dielectric varies in thickness to product a color palette.

### CROSS-REFERENCE TO RELATED APPLICATIONS

This application claims priority to and is a continuation-in-part for U.S. patent application Ser. No. 11/956,911 which claims priority from U.S. Provisional Patent Application Ser. No. 60/884,768, titled PRESERVATION/STORAGE OF DATA AS IMAGES ON SILICON WAFERS USING NANOTECHNOLOGY, filed Jan. 12, 2007, all of which are hereby incorporated in their entirety by reference.

### FIELD OF THE INVENTION

This invention relates to the long-term storage of images on substrates that can be processed using semiconductor fabrication techniques, and more particularly to the long-term storage of color images on silicon wafer substrates.

### BACKGROUND

As unique documents are created, the desire to back-up those documents also increases the need to archive those documents. On an individual level, information such as letters, deeds, financial documents, photographs and such are preserved for sentimental, personal, and financial reasons. Federal institutions invest time and money to preserve legislative, executive, judicial documents, as well as birth and death records of the citizens. Historical documents are archived to retain the information stored within them as the documents deteriorate with age and become brittle. The archived copies can provide access to the information in the event the original document is lost or destroyed and can further provide multiple copies for access to numerous individuals.

Due to the sheer volume of the number of documents, paper-based storage is expensive and very cumbersome. Furthermore, paper is susceptible to environmental hazards such as water and fire. Paper documents do not age well with time unless great care is taken to preserve the paper. As a result, alternative storage techniques such as microfilm/microfiche and electronic memory were developed.

In microfilm technology, images are with black and white photographic process. This process utilizes image reduction techniques to reduce the size of images which are later exposed to photosensitive films. These films are then preserved in a controlled environment for long-term preservation. However, this technology requires special microfilm viewers to view the images. Furthermore, high-quality hard-copy reproduction is expensive and the duplication process is difficult. In addition to these disadvantages, color images are not possible.

Another form of archiving is electronic storage. Data is stored electronically in the form of digital bits and using integrated circuits and magnetic, optical or semiconductor memory. Semiconductor memory can be broadly classified as either volatile and non-volatile. Volatile memory requires electrical power to retain information, while non-volatile memory can retain stored information even when not powered. An example of volatile memory is random access memory (RAM) used in most computers. Non-volatile memory includes semiconductor based flash memory, read-only memory (ROM) and most magnetic storage and optical disc storage such as CD ROMs and DVD ROMs. However, even though the semiconductor memory stores the data in a compact area, the data itself is processed and digitized prior to storage. The information must be converted to digital bits, which are represented in various forms depending on the medium of storage. For example, the letter “A” is converted into a series of ones and zeros representative of a coded byte. In order to convert the stored code back to a human readable letter, the user must have a computer with an operating system and a decoder which can recognize the coded byte and display it as an “A.”

In semiconductor memory, the digital bits are represented by different voltage levels that are stored using integrated circuits and/or capacitors. On CD ROMs the bits are represented as “pits” and “grounds” that reflect a laser in different ways to read the CD ROM. In most semiconductor memory applications the digital bits are encoded prior to storage, and thus require a decoding technique for retrieving the data. This digitalization of data prior to storage can result in quantization losses. Furthermore, semiconductor memory depends very much on the current mainstream technology, thereby forcing the users to upgrade frequently to new types of storage media and media reading devices.

Therefore, a stable long-term image archiving system capable of storing a large number of images in a compact medium is desired.

Further, an archiving medium that is resistant to fire, water and time deterioration is desired.

Yet further, the storage of color images is desired.

### SUMMARY

The invention comprises, in one form thereof, a system for the long-term storage of images stored on semiconductor substrates. The images are stored by utilizing semiconductor fabrication techniques such that, with magnification, the images are visible to the human eye. Datasets from print, digital or other media are converted to an image. The images are transferred to the silicon wafer substrate by methods such as photolithography tools, nanotechnology fabrication techniques and direct maskless lithography technologies. To produce color images, the thickness of layers are varied to produce distinct colors.

An image organization software program organizes the images and generates a location images, such as a barcode. The image organization software program further generates metadata associated with each image and stores that metadata both in an electronic database and on the metadata associated with the barcode associated with that particular image. Each location image is a unique identifier that contains both the metadata and the location information for each specific image on the silicon wafer substrate. The images and location image are then transferred to specific predetermined locations on the silicon wafer substrate.

The stored images are easily retrieved by use of a first software program. The first software program searches for the user's queries in the electronic database and sends the metadata relating to that particular image to the image reader. The image reader scans the location image to identify the location of the images on the wafer. The image reader then transmits the location information to the system and drives either the optics over the silicon wafer or the wafer itself to the appropriate location relative to the optical system. The desired image is then displayed for the user. Once a request for an image is submitted, the entire process can be completed in a few milliseconds.

An advantage of the present invention is that the long term storage of color images is possible.

A further advantage of the present invention is that the images retain excellent image quality over time.

An even further advantage of the present invention is that the use of silicon wafer substrates makes the images resistant to damage by fire and water.

### BRIEF DESCRIPTION OF THE DRAWINGS

The present invention is disclosed with reference to the accompanying drawings, wherein:

FIG. 1 is a flowchart demonstrating the capture, storage and retrieval of images according to one embodiment;

FIG. 2 is a process flow chart for silicon image preservation according to one embodiment;

FIG. 3 is a process flow diagram according illustrating the various steps involved in varying the film thickness according to one embodiment;

FIG. 4 is a process flow diagram according illustrating the various steps involved in varying the film thickness according to one embodiment;

FIG. 5 is a process flow diagram illustrating the various steps involved in a lithography process according to one embodiment; and

FIG. 6 is a schematic of a silicon-wafer reader according to one embodiment.

Corresponding reference characters indicate corresponding parts throughout the several views. The examples set out herein illustrate several embodiments of the invention but should not be construed as limiting the scope of the invention in any manner.

### DETAILED DESCRIPTION

This invention relates to storing images on semiconductor substrates, particularly for long-term preservation using imaging and semiconductor fabrication techniques. In this technique, the images are stored in such a way that they are visible to the human eye usually with magnification, though it is possible to view large-scale images without magnification. Printed documents, digital files, or any other media are converted to images. These images, with the help of photolithography tools and fabrication techniques, are then imprinted and etched on semiconductor substrates, such as silicon wafers. Once the images are embedded onto the wafer it is possible to have over 6000 images on a single wafer. The use of silicon makes the information resistant to both high temperatures up to 400° C. and water exposure ensuring longevity, which is very useful in preserving documents. Since the stored images are not digitized, the images can be stored for long periods in its original, human readable format without degrading over time. One advantage of this technique is retrieval of the images can be as simple and straightforward as magnifying the image on the semiconductor substrate thereby eliminating the need for a computer or complex reading devices. This feature enables archival of images in an environment independent of computer operating systems, decoders and other application programs. Furthermore, based on the semiconductor fabrication technique used, nano-scale images can be produced thereby making it possible to store large quantities of data on each single semiconductor substrate. The nano-scale images can have features smaller than 90 nm in one embodiment and features as small as 1 micron in another embodiment. Another advantage of the semiconductor fabrication technique is the ability to deposit various layers of metal, polysilicon, and polymers vertically on the silicon substrate. This method of depositing different layers vertically can be used to encrypt the image for security. The encrypted images can then be read using dedicated instruments.

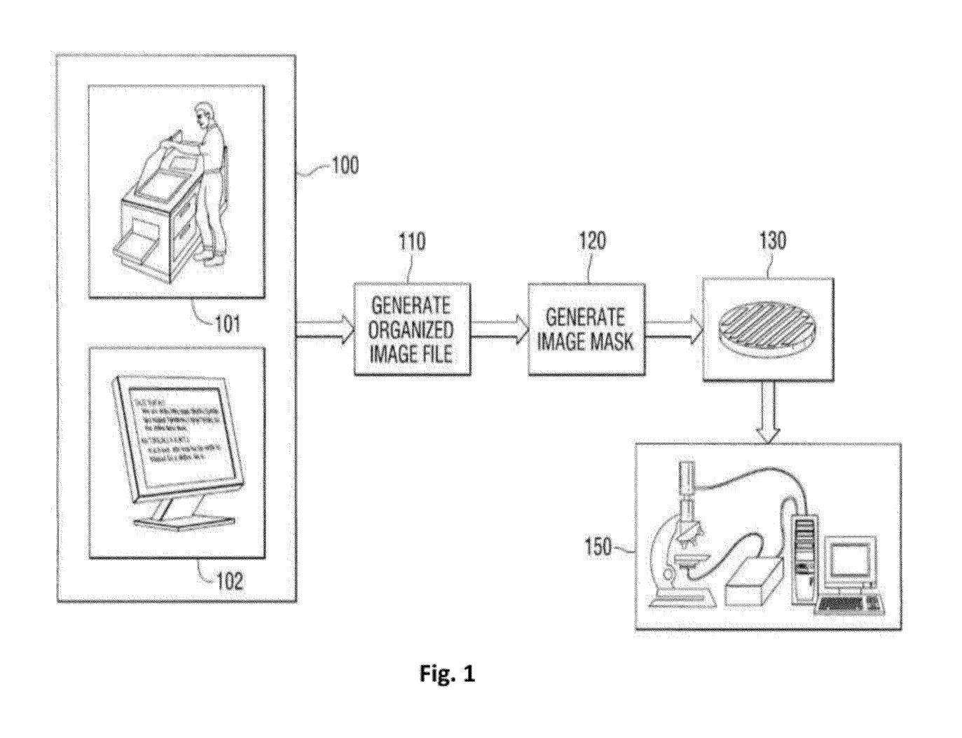

Referring to FIG. 1, there is shown a process flow chart according to one embodiment. During the image collection step 100 image files are generated. The image files can be user generated image files 101, that are transferred directly from a user's computer or storage medium. Alternatively, the image files can be created image files 102. These created image files 102 are generated from viewable sources such as books, manuscripts, maps, photographs, microfiche, microfilm, checks, drawings, maps, photographs or electronic documents. The viewable sources are scanned and converted into an image file. A first software program generates an organized image file 110. The organized image file 110 is a file containing a layout of the gathered images. This organized image file is then reproduced on the semiconductor substrate. The images are arranged such that, if possible, all images will fit on a single wafer. Optionally, the first software program generates at least one location image containing location information, such as a barcode. In generating the organized image file 110, the first software program assigns a location to each image file. This location information is encoded into a location image. A single location image can contain location information for a plurality of individual images. The first software program further generates metadata for each image. The metadata contains the wafer information for which the image is stored on, the location image associated with the image, and optionally any details or description of the image.

In use, the images need to be collected. The document or information is converted to a bitmapped digital image. For example, the information from print media such as books, manuscripts, microfilms, or microfiche is captured using a high-resolution camera and converted to digital images. Alternatively, an electronic file may be converted to digital images.

Once a digital image is obtained the digital image is scaled to the desired size by associating each pixel to a minimum spot size which is limited by the fabrication process. During the scaling process each digital image is represented by the number of pixels in both the X and Y coordinates as well as the resolution expressed in dots per inch (DPI). For example, in a two micron fabrication facility the minimum spot size is two microns. As a result the smallest character size for a two micron facility is 10 microns. Therefore, an image that consists of 6080×1520 pixels at 300 dpi is converted to 12160×3040 microns.

In the reduction process, standard size images are reduced to smaller dimensions. For example, using the 200 nm fabrication technology, character sizes are reduced to 20 microns. Using this technique a standard legal paper (8½ by 11 inches) can be reduced to fit in an area of 2.68 mm². At this resolution, a 6-inch wafer can store about 6590 legal-size pages. In one embodiment an 8″ diameter wafer is used. It is understood that other standard wafer sizes such as 4″ or 12″ diameter, or custom sized wafers can be used. The wafer may be single or dual-sided depending on the storage needs. In addition, new fabrication techniques with smaller feature sizes allow for further increases in storage capacity by further reducing the image size.

The obtained digital images are converted to bit-mapped files such as uncompressed Tiff files. The images are then transferred to a silicon wafer substrate by utilizing photolithography tools, nanotechnology fabrication techniques or direct maskless lithography technologies.

In one embodiment the semiconductor substrate is single-side mirror polished 150 mm test-grade silicon wafer that was grown using the CZ method having a thickness of about 650+/−25 micron. In another embodiment the wafer is a dual-sided wafer. There are many known techniques for processing dual-sided wafers. For example, one of the most common techniques is sequential processing. In this process one side of the wafer is processed completely and then the other side is processed.

Polycrystalline silicon wafers may also be used. Polycrystalline silicon has the same durability as monocrystalline wafers. Unless directional etching is required, a polysilicon substrate will perform as well as a monocrystalline structure. Polysilicon is less expensive than monocrystalline material. It has the added advantage of being able to be formed into other shapes such as square and rectangular cross-sections. The rectangular shape provides less wasted image space than a circular wafer. Other geometric cross-sectional shapes include, but are not limited to, triangles, ellipses, pentagons, hexagons, octagons, and other polygons.

Referring again to FIG. 1, an image mask 120 is generated from the results of the organized image file 110. The image mask 120 is utilized to fabricate a silicon wafer 130 having the organized image file embedded thereon. The silicon wafer 130 is then packaged in a transparent material such as Fluoroware Model No. H93-60. It is understood that custom packaging and designs can be utilized without departing from the scope of the invention.

The images retained on the silicon wafer are retrieved by the wafer reader 150. A user requests a particular image from a computer system. The computer system then reads the metadata relating to that image and transmits the appropriate location image to the wafer reader 150 which scans the location image on the wafer. The wafer reader 150 decodes the appropriate location image containing the location information for the desired image. The location information is transmitted to the drive system which then orients the desired image under the optics for imaging and the image is magnified and transmitted to a display.

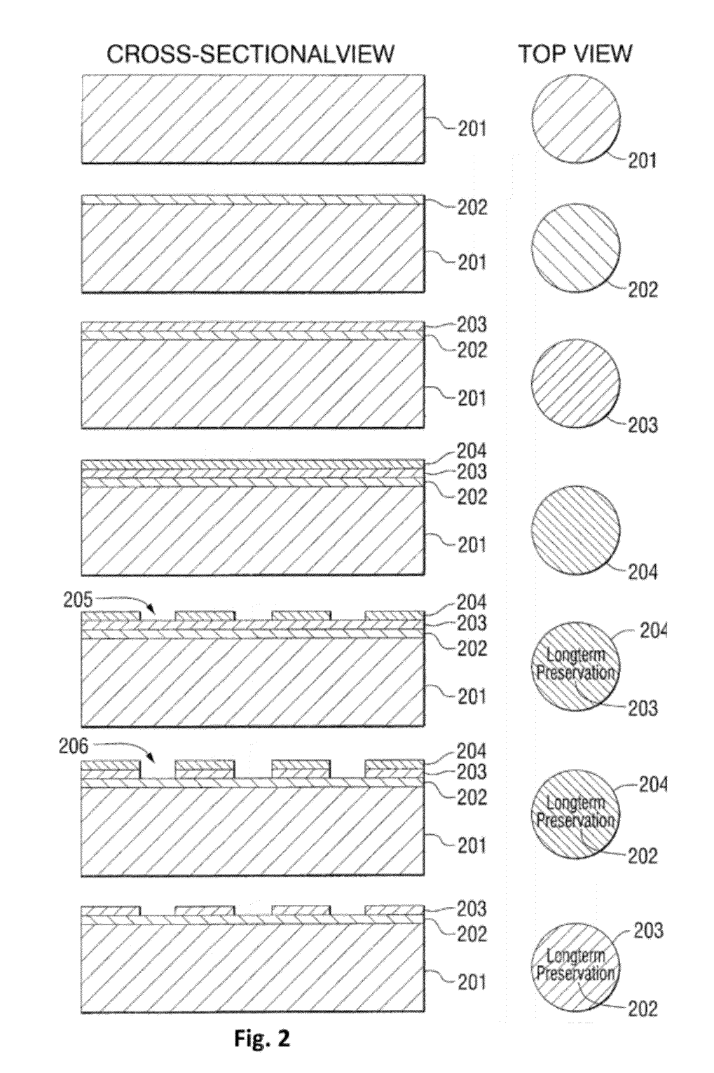

Referring to FIG. 2, there is shown a process flow chart for preserving an image on a semiconductor substrate. It is understood that any suitable semiconductor substrate processing technique may be used to preserve the image. The process begins with a silicon substrate 201. A silicon dioxide layer 202 is grown or deposited over the silicon substrate 201. In one embodiment the silicon dioxide layer is about 1 μm thick. A metal layer 203 is then deposited over the silicon dioxide layer 202. In one embodiment the metal is aluminum in a 0.4-μm-thick layer. A photoresist layer 204 is deposited over the metal layer 203. Using the mask previously generated, and traditional lithography techniques, portions of the photoresist layer 205 are removed to form an image representative of the organized image file. In one embodiment the photoresist is patterned by using flood exposure techniques. The photo-resist is developed and removed exposing portions of the metal layer. The portions of the metal layer 206 that are exposed are then removed by etching. In one embodiment, an anisotropic wet etch is used. In an alternative embodiment, a dry plasma etch is used. The remaining photoresist removed, leaving the image embedded in the metal layer 203. Additional layers may be deposited over the metal layer to assist in preserving or encrypting the image, such as a passivation layer of SiO₂. that is typically about 100 Å, or 10 nm thick.

Color images are formed by varying the thickness of the oxide layer. During the scanning process, a small area of the image is associated with a particular bit-mapped. That color is then referenced to a corresponding thickness in the oxide layer, which would reflect that color. A broad selection of colors are represented by the appropriate oxide thickness. Table 1 lists the apparent color under fluorescent lighting for a variety of oxide layer thicknesses over a silicon wafer substrate. Some of the represented colors respond in a cyclical manner. That is, the color is repeated at multiple thickness of the oxide layers. Therefore, the same color can be reflected and distinct thicknesses.

TABLE 1

| Oxide Thickness | |
|---|---|
| (angstroms) | Apparent color under typical fluorescent lighting |
| 0 | black |
| 500 | tan |
| 700 | brown |
| 1000 | dark violet to red violet |
| 1200 | royal blue |
| 1500 | light blue to metallic blue |
| 1700 | metallic to very light yellow-green |
| 2000 | light gold or yellow - slightly metallic |
| 2200 | gold with slight yellow-orange |
| 2500 | orange to melon |
| 2700 | red-violet |
| 3000 | blue to violet-blue |
| 3100 | blue |
| 3200 | blue to blue-green |
| 3400 | light green |
| 3500 | green to yellow-green |
| 3600 | yellow-green |
| 3700 | green-yellow |
| 3900 | yellow |
| 4100 | light orange |
| 4200 | carnation pink |
| 4400 | violet-red |
| 4600 | red-violet |
| 4700 | violet |
| 4800 | blue-violet |
| 4900 | blue |
| 5000 | blue-green |
| 5200 | green |
| 5400 | yellow-green |
| 5600 | green-yellow |
| 5800 | light orange or yellow to pink |
| 6000 | carnation pink |
| 6300 | violet-red |
| 7200 | blue-green to green |
| 8000 | orange |
| 8200 | salmon |
| 8500 | dull light red-violet |
| 8600 | violet |
| 8700 | blue-violet |
| 8900 | blue |
| 9200 | blue-green |
| 9500 | dull yellow-green |
| 9700 | yellow |
| 9900 | orange |

In one embodiment, distinct color images are produced on the semiconductor substrate by applying a single blanket thin-film dielectric layer coating to the semiconductor substrate and then etching different parts of the dielectric layer to lower the thickness to produce the collection of colors desired. In one embodiment the initial thin-film dielectric layer is the thickest color desired with all other colors being obtained by reducing the thickness of the dielectric layer in specific areas.

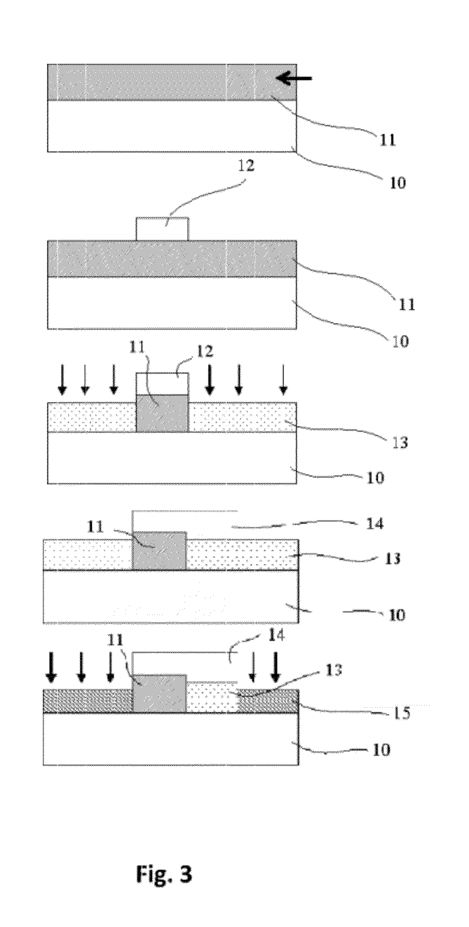

Referring to FIG. 3, there is shown a process flow diagram according to one embodiment. A thin-film dielectric 11 is deposited or grown over a semiconductor substrate 10. The thin-film dielectric can be any reasonably transparent thin-film dielectric material that demonstrates color finges as a function of material thickness and refractive index. In one embodiment the thin-film dielectric is silicon oxide. In another embodiment the thin-film dielectric is silicon nitride. In one embodiment the semiconductor substrate is a silicon wafer.

Referring again to FIG. 3, a photoresist is deposited over the thin-film dielectric 11, exposed and the developed resist removed to retain the undeveloped photoresist 12 as a mask over the thin-film dielectric 11. The exposed portion of the thin-film dielectric layer 11 is partially etched to form a thinner layer 13 of the dielectric layer. This results in a thin-film dielectric layer having two thicknesses 11 and 13. A second photoresist is applied, exposed and the developed portion removed to leave an undeveloped resist mask 14 on the thin-film dielectric 11 and a portion of the thinner portion 13. The exposed surface of the thinner layer 13 is then etched to form a third layer 15 of the thin-film dielectric. The photoresist is then removed leaving a three tiered thin-film dielectric layer. Each tier corresponding to a distinct color. By varying the size of each tier portion a plurality of colors can be represented. Although a three tier thin-film dielectric is described above it is understood that additional tiers can be implemented by repeating the above process. For example a 16, 32 or 256 tier dielectric can be used for improved and broader color representation.

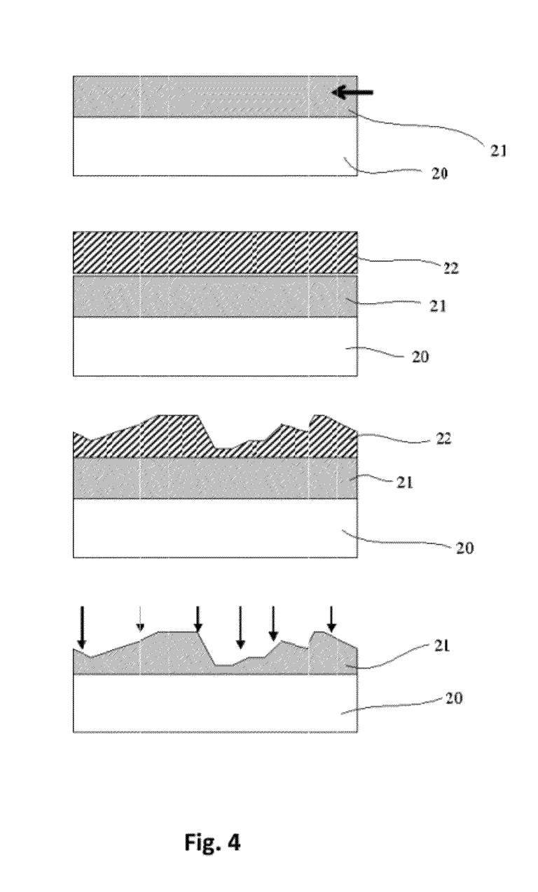

In another embodiment, discrete exposure such as grey-scale lithographic processes or maskless lithographic techniques are utilized to produce a much broader color range. Referring to FIG. 4, A thin-film dielectric 21 is deposited or grown over a semiconductor substrate 20. The thin-film dielectric can be any reasonably transparent thin-film dielectric material that demonstrates color finges as a function of material thickness and refractive index. In one embodiment the thin-film dielectric is silicon dioxide. In another embodiment the thin-film dielectric is silicon nitride. In one embodiment the semiconductor substrate is a silicon wafer.

The photoresist 22 layer is deposited above the thin-film dielectric 21. The photoresist 22 is then partially exposed, the exposed portion softens and is removed resulting in a contoured surface in the photoresist 22. Partial exposure varies the exposure of different portions of the photoresist 22 from 0 to 100%. Only the exposed resist is stripped away. For example, if a portion of the photoresist layer is given only 10% of its nominal dose-to-clear, then approximately 90% of the thickness of the photoresist layer will remain after exposure. By varying the light dosage applied to different areas of the photoresist, a contoured surface is formed. In one embodiment the partial exposure creates a plurality of discrete exposure levels. For example, the Heidelberg DWL2000 exposure tool can obtain 128 discrete levels in the photoresist.

Although the photoresist layer 22 having a contoured surface will exhibit color variations as a function of thickness, the photoresist layer is not a robust archive medium. The photoresist layer and a portion of the thin-film dielectric layer are etched to form a contoured surface in the thin film-dielectric 21. In one embodiment the etch is performed by an argon ion beam that erodes the photoresist layer and the thin-film dielectric layer at approximately the same rate. The contours of the photoresist are essentially transferred to the thin film-dielectric. Optionally, the thin-film dielectric is coated in an additional layer to provide protection, color enhancement, encryption or the like.

In another embodiment maskless lithography systems are used. Direct write, maskless lithography systems such as the SF-100×PRESS can produces features as small as 1 micron. By varying the exposure of the laser, the thickness of the oxide can be varied to generate the varied thicknesses and produce the desired color images.

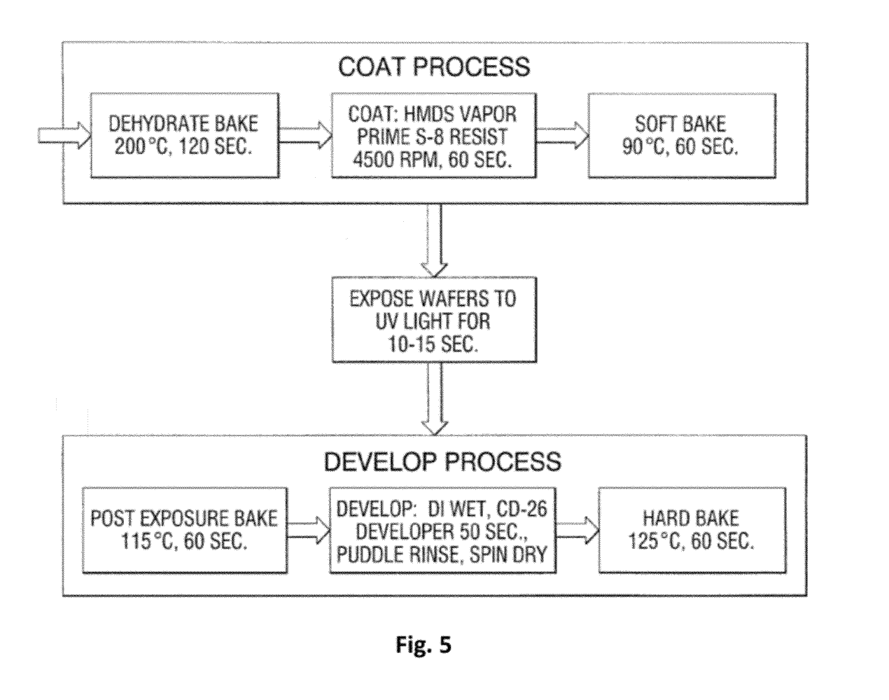

Referring to FIG. 5 there is shown a process flow chart illustrating the various steps involved in a lithography process. The wafers are coated with a passivation layer and metal and are patterned using the various fabrication steps. The photolithography process consists of three stages coat, expose and develop. First, the wafers are coated with a positive photoresist (S-8). Second, the photoresist is exposed to UV light with a clear field mask. The clear regions on the mask allow light to pass through thereby dissolving the photoresist at that location, and thereby creating the desired pattern. The pattern on the mask corresponds to the organized image file. Third, the pattern is developed by using a developer such as CD26. After developing the wafers are ready for additional process steps such as an aluminum etch. While traditional mask lithography techniques are described, it is understood that the direct write maskless lithography systems can be used without detracting from the invention.

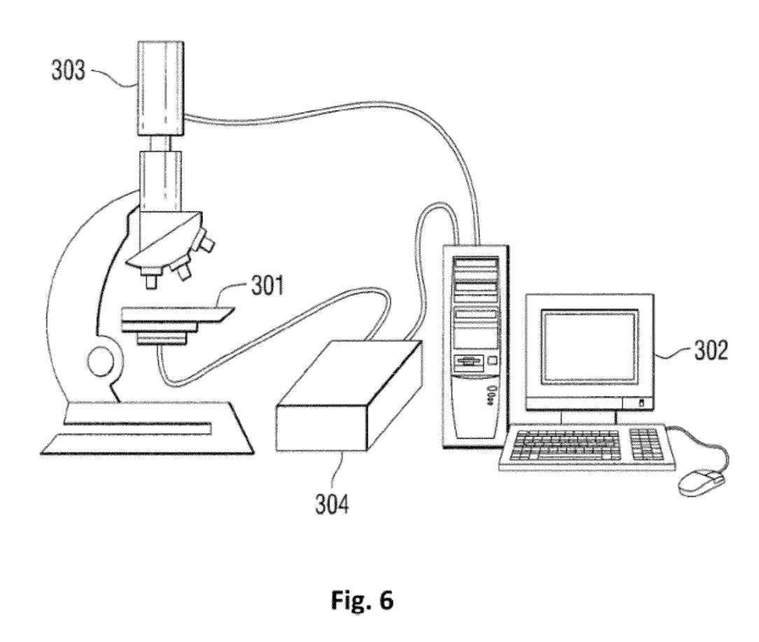

Referring to FIG. 6, there is shown a wafer-reading device according to one embodiment. To retrieve an image a user enters the image request into the image retrieval system 300. The computer 302 accesses the previously stored metadata and transmits the barcode information for the desired image to the camera 303. The camera scans the barcode image, which is located at a predetermined location on the wafer, and transmits the barcode image to the computer 302. The a software program residing on the computer 302 decodes the barcode. The barcode contains the location information for the image such as the X and Y coordinates on the wafer. The computer 302 transmits the location information to the alignment device 304, and the alignment device 304 positions the silicon wafer such that the camera 303 can scan the desired image. The camera 303 transmits the image file to the computer 302, which then displays the image.

In one embodiment, it is desirable to reduce the size of the location image to allow more space for other image files. In one embodiment each location image contains location information for a plurality of images. The size of the location image is about the same size as the other images on the wafer. After the location image is scanned by the camera the image is transmitted to the computer. A custom software program extracts the individual document location and transmits the X and Y coordinates to the alignment device.

For systems containing multiple wafers each wafer is labeled and the proper wafer is loaded onto the wafer reader. In one embodiment RFID tags are used for identifying the wafer. RFID tags are efficient in the retrieval of a wafer in a system containing a large collection of wafers. In one embodiment the wafer reader equipment has the necessary electronics attached to robotic arms. The robotic arms scan the RFID tags for the correct wafer. The robotic arm then removes the correct wafer and positions the wafer on the wafer reading plate. Because the system scans the RFID tags it is not necessary for the wafer to return to its original location. It is understood that any cataloging system can be used to organize the wafers for storage and access.

Wafers typically have a single or double notch that can be used for alignment once placed on the wafer reading plate. Optical indicators at predetermined positions can also be used as alignment marks and reference points.

After a user queries the database that has the metadata and gets a list of possible matches as an output from the system and the proper wafer is placed on the wafer reading plate. The wafer is aligned, the barcode image is scanned and the barcode information is transmitted. The system transmits the X and Y coordinates of the desired image and the spacing between the documents to the alignment device. Using this information the alignment device drives the stage to the desired location. In an alternative embodiment the stage is stationary and the camera is driven to the desired location.

The camera transmits the image to the display. In one embodiment the camera generates a digital image that is obtained by using optics and magnification. In the event the wafer is encrypted the system will be equipped with an encryption reader. The encrypted readers is designed to look for predefined patterns on the wafer. Once the patterns are identified the reader collects the data of the various layers on the wafer and reconstruct the desired output using a custom encryption software program.

In yet another embodiment, the invention contains a semiconductor substrate having a plurality of images and an image location device thereon. At least ten percent of the images are unique and distinct from the other images on the substrate. The image location device represents the location of one or more images on the substrate. For example, the image location device can be an image of barcodes containing the X and Y coordinates for the images on the substrate. Alternatively, the image location device can be an image of spreadsheet containing a reference to each image and the location information for that image.

While the invention has been described with reference to particular embodiments, it will be understood by those skilled in the art that various changes may be made and equivalents may be substituted for elements thereof without departing from the scope of the invention. In addition, many modifications may be made to adapt a particular situation or material to the teachings of the invention without departing from the scope of the invention.

Therefore, it is intended that the invention not be limited to the particular embodiments disclosed as the best mode contemplated for carrying out this invention, but that the invention will include all embodiments falling within the scope and spirit of the appended claims.

1. An image archival device comprising:
a. a semiconductor substrate having at least one orientation indicator; and
b. a transparent thin-film dielectric layer over said semiconductor substrate that varies in thickness to produce distinct hues that correlate to the thickness of the transparent thin-film dielectric layer;
the distinct hues producing a plurality of bit-mapped color images.

2. The image archival device of claim 1, wherein said semiconductor substrate is a silicon wafer.

3. The image archival device of claim 1, wherein said transparent thin-film dielectric layer is deposited on the semiconductor substrate.

4. The image archival device of claim 4, wherein said transparent thin-film dielectric layer is SiO₂ or Si₃N₄.

5. The image archival device of claim 1, wherein the thickness of said transparent thin-film dielectric layer is between 0 and 9900 Angstroms.

6. The image archival device of claim 5, wherein the transparent thin-film dielectric layer is a color filter.

7. The image archival device of claim 1, wherein said plurality of images is at least 100 distinct images.

8. The image archival device of claim 1, wherein said transparent thin-film dielectric layer is grown on said semiconductor substrate.

9. The image archival device of claim 1, wherein said transparent thin-film dielectric layer comprises at least 16 distinct thicknesses.

10. A method for forming a plurality of images on a semiconductor substrate comprising the steps of:
a. providing a semiconductor substrate;
b. depositing a transparent thin-film dielectric layer over said semiconductor substrate having a first thickness that reflects a first color;
c. partially etching the portions of the transparent thin-film dielectric layer to form a varying thickness in the thin-film dielectric layer;
the different thicknesses reflecting different colors creating a pattern representative of a plurality of color images.

11. The method of claim 10, wherein the step of partially etching portions of the transparent thin-film dielectric layer comprises further comprising the steps of:
a. applying a first photoresist mask over portions of said transparent thin-film dielectric layer;
b. partially etching the portions of the transparent thin-film dielectric layer not covered said first photoresist mask to form a second thickness that reflects a second color;
c. repeating the foregoing steps of applying a photoresist mask and partially etching portions of the dielectric layer to create multiple regions of different thicknesses that reflect different colors.

12. The method of claim 11, wherein said transparent thin-film dielectric layer has at least three distinct thicknesses.

13. The method of claim 10, wherein said transparent thin-film dielectric layer has at least 16 distinct thicknesses.

14. The method of claim 13, wherein said plurality of images is at least 100 distinct images.

15. The method of claim 10, wherein the step of partially etching the portions of the transparent thin-film dielectric layer is performed utilizing maskless lithography techniques.

16. The method of claim 10, wherein the step of partially etching portions of the transparent thin-film dielectric layer comprises further comprising the steps of:
a. applying a photoresist mask over said transparent thin-film dielectric layer;
b. discreetly exposing said photoresist to an image of variable light intensity to selectively develop the photoresist in accordance with the variable light intensity to form a contoured undeveloped surface;
c. removing the developed portion of said photoresist retaining the contoured undeveloped surface;
d. etching said photoresist and said transparent thin-film dielectric layer with a substance that removes said transparent thin-film dielectric layer and said photoresist at the same rate to transfer the contoured surface in said photoresist to said transparent thin-film dielectric layer.

17. The method of claim 16, wherein said etch is an argon ion beam etch.

18. A method for retaining images on a semiconductor substrate comprising:
scanning a plurality of images;
condensing the plurality of images to a bit-mapped image file, such that the image file organizes the plurality of images to fit on a silicon wafer;
writing the bit-mapped image file onto a silicon wafer substrate as a plurality of half-toned images utilizing maskless lithography techniques; and
writing an image location device onto a silicon wafer as part of said bit-mapped image file utilizing maskless lithography techniques, said image location device containing the location information for at least one of said plurality of images located on said silicon wafer.

19. The method of claim 18, wherein said bit-mapped image file is an uncompressed TIFF image file.

20. The method of claim 18, wherein said maskless lithography techniques produce feature sizes of less than two microns.
